(19) United States
(12) Patent Application Publication
(10) Pub. No.: US 2026/0128215 A1
(43) Pub. Date: May 7, 2026

(54) Multilayer Component, Multilayer Component Assembly, and Methods for Forming a Multilayer Component

(71) Applicant: KYOCERA AVX Components Corporation, Fountain Inn, SC (US)

(72) Inventors: Caleb Winfrey, Simpsonville, SC (US); Cory Nelson, Simpsonville, SC (US); Jonathan Herr, Taylors, SC (US)

(21) Appl. No.: 19/366,622

(22) Filed: Oct. 23, 2025

Related U.S. Application Data
(60) Provisional application No. 63/716,258, filed on Nov. 5, 2024.

(51) Int. Cl. H01G 2/14; H01G 4/30; H05K 1/02; H05K 1/11; H05K 1/18

(52) U.S. Cl. CPC H01G 2/14; H01G 4/30; H05K 1/0218; H05K 1/115; H05K 1/182; H05K 2201/10015

(57) ABSTRACT

Multilayer components, assemblies, and methods for forming multilayer components and assemblies are provided. For example, a multilayer component includes a plurality of dielectric layers, including an outer dielectric layer, that are stacked in a Z-direction to form a substrate having a top and a bottom; a conductive layer formed over a respective one dielectric layer and disposed within the stacked plurality of dielectric layers such that the conductive layer is spaced apart from both the top and the bottom of the substrate along the Z-direction; a shield layer formed over the outer dielectric layer; and a plurality of vias extending from the shield layer. The plurality of vias can be electrically connected to a ground defined on a substrate of a device; the multilayer component can be mounted on a surface of the device or embedded within the device.

### RELATED APPLICATIONS

The present application is based upon and claims priority to U.S. Provisional Patent Application Ser. No. 63/716,258, having a filing date of Nov. 5, 2024, which is incorporated herein by reference.

### FIELD

The present disclosure relates to multilayer components, such as capacitors and inductors, as well as multilayer component assemblies and methods of manufacturing thereof.

### BACKGROUND

The diversity of modern technical applications creates a need for efficient electronic components and integrated circuits. Components such as capacitors and inductors, among others, are fundamental components used for filtering, coupling, bypassing, and other aspects of such modern applications which may include wireless communications, alarm systems, radar systems, circuit switching, matching networks, and many other applications. A dramatic increase in the packing density of integrated circuits, which can reduce their overall size or space occupied thereby, requires advancements in technology of the constituent components of such circuits. For example, packing a greater number of components more closely together can degrade the performance of an individual component, e.g., due to interference from one or more neighboring components.

Many specific aspects of component design, such as capacitor design and inductor design, have thus been a focus for improving their performance characteristics, particularly when embedding or otherwise including such components in circuits or the like.

### SUMMARY

In accordance with one embodiment of the present invention, a multilayer component includes a plurality of dielectric layers including an outer dielectric layer, the plurality of dielectric layers stacked in a Z-direction to form a substrate having a top and a bottom; a conductive layer formed over a respective one dielectric layer of the plurality of dielectric layers, the conductive layer disposed within the stacked plurality of dielectric layers such that the conductive layer is spaced apart from both the top and the bottom of the substrate along the Z-direction; a shield layer formed over the outer dielectric layer; and a plurality of vias extending from the shield layer.

In accordance with another embodiment of the present invention, an assembly includes a device having a device substrate and a ground defined on the device substrate; and a multilayer component attached to the device substrate.

The multilayer component includes a plurality of dielectric layers including an outer dielectric layer, the plurality of dielectric layers stacked in a Z-direction to form a multilayer component substrate having a top and a bottom; a conductive layer formed over a respective one dielectric layer of the plurality of dielectric layers, the conductive layer disposed within the stacked plurality of dielectric layers such that the conductive layer is spaced apart from both the top and the bottom of the multilayer component substrate along the Z-direction; a shield layer formed over the outer dielectric layer; and a plurality of vias extending from the shield layer.

Each via of the plurality of vias is electrically connected to the ground.

In accordance with still another embodiment of the present invention, a method for forming a multilayer component includes forming a plurality of dielectric layers, the plurality of dielectric layers including an outer dielectric layer; forming a conductive layer, the conductive layer formed from a conductive material disposed over a respective one dielectric layer of the plurality of dielectric layers; forming a shield layer, the shield layer formed from the conductive material disposed over the outer dielectric layer; stacking the plurality of dielectric layers in a Z-direction to form a substrate; and defining a plurality of vias along the perimeter of the substrate. The plurality of vias extend from the shield layer to an outer surface of the substrate opposite the shield layer along the Z-direction.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 illustrates a schematic cross-section view of an assembly of the prior art;

FIG. 2 illustrates a schematic cross-section view of an assembly including a multilayer component of the present invention;

FIG. 3 illustrates a top perspective view of the multilayer component of FIG. 2;

FIG. 4 illustrates a schematic cross-section view of an assembly of the present invention;

FIG. 5 illustrates a schematic cross-section view of another assembly including a multilayer component of the present invention;

FIG. 6 illustrates a top perspective view of the multilayer component of FIG. 5;

FIG. 7 illustrates a schematic cross-section view of another assembly including a multilayer component of the present invention;

FIG. 8 illustrates a top perspective view of the multilayer component of FIG. 7; and

FIG. 9 provides a flow chart of a method for forming a multilayer component of the present invention.

Repeat reference to characters in the present specification and figures is intended to represent same or analogous features or elements of the invention.

### DETAILED DESCRIPTION

It is to be understood by one of ordinary skill in the art that the present discussion is a description of exemplary embodiments only and is not intended as limiting the broader aspects of the present invention.

Generally speaking, the present invention is directed to multilayer components, such as multilayer capacitors, multilayer inductors, multilayer filters, or the like, that include a shield layer that shields the multilayer component from interference. As one example, a multilayer capacitor as described herein can include a plurality of layers that form a substrate with a first conductive layer overlapping a second conductive layer to form a capacitor and a shield layer connected to a plurality of vias. The plurality of vias can be connected to a ground to form a grounded “cage” about the capacitor to protect the capacitor against electronic interference. As described herein, the multilayer components may be embedded in a device, such as a printed circuit board, to form a multilayer component assembly, and the present disclosure also includes methods of forming such multilayer components and multilayer component assemblies.

In some embodiments, a multilayer component includes a plurality of dielectric layers, including an outer dielectric layer, that are stacked in a Z-direction to form a substrate having a top and a bottom. The outer dielectric layer can be disposed at the top of the substrate, and a shield layer is formed over the outer dielectric layer. The multilayer component includes at least one further conductive layer formed over a respective dielectric layer of the plurality of dielectric layers.

For example, in some embodiments, the multilayer component is a capacitor and includes at least two conductive layers that are each formed over a respective dielectric layer of the plurality of dielectric layers. In other embodiments, the multilayer component is an inductor and includes a conductive layer formed over a dielectric layer of the plurality of dielectric layers. In further embodiments, the multilayer component is a filter or a component that is more than a single type of element, e.g., the multilayer component can be or can include more than only a capacitor or only an inductor.

Further, the substrate defines a perimeter, and a plurality of vias may be defined along the perimeter of the substrate. The plurality of vias can extend along the Z-direction from the shield layer to the bottom of the substrate. In at least some embodiments, the vias may be grounded such that the shield layer forms a grounded shield of the multilayer component. That is, one or more of the vias defined along the perimeter of the substrate can be electrically connected to a ground and electrically connected to the shield layer, which includes a conductive material formed over a dielectric layer such that the grounded via(s) connected thereto ground the shield layer to form a shield along the top of the multilayer component where the shield layer is located, as well as along the sides of the multilayer component where the vias are defined. Thus, the shield forms a grounded “cage” about the multilayer component, which can provide protection from interference for the multilayer component and/or can improve performance and/or rejection compared to multilayer components having a similar footprint but lacking such grounded shield.

The plurality of dielectric layers in a multilayer component as described herein may include one or more dielectric materials. In some embodiments, the one or more dielectric materials may have a low dielectric constant (K). The dielectric constant may be less than about 20, in some embodiments less than about 10, in some embodiments less than about 7.5, in some embodiments less than about 5, in some embodiments less than about 4.5, in some embodiments less than about 4, and in some embodiments less than about 3.5. For instance, in some embodiments, the dielectric constant may range from about 1.5 to about 20, in some embodiments from about 1.5 to about 10, in some embodiments from about 1.5 to about 7.5, and in some embodiments from about 2 to about 5.

Such a relatively low dielectric constant material may allow the dielectric layers to be very thin or ultrathin, which can allow the multilayer component substrate to be thinner than typical components. Although a relatively low dielectric constant material usually becomes brittle as its thickness is reduced or it is made thinner, the multilayer stack of dielectric layers and conductive layer(s) as described herein provides sufficient stiffness to avoid negative effects of brittleness of the individual layers. Further, lower dielectric constant materials may have better high frequency performance than higher dielectric contact materials. Accordingly, the present inventors have discovered that the combination of the plurality of dielectric layers formed from a relatively low dielectric constant material and the arrangement of the plurality of dielectric layers in a stack as described herein can result in smaller components, such as smaller capacitors, smaller inductors, etc., with improved high frequency performance than known components. Moreover, the present inventors have discovered that incorporating a shield in the multilayer stack as described herein can provide the advantages of shielding without enlarging the component footprint, i.e., the advantages of shielding may be achieved while maintaining the size improvements as described herein.

In some embodiments, the one or more dielectric materials may include organic dielectric materials. Example organic dielectric include polyphenyl ether (PPE) based materials, such as LD621 from Polyclad and N6000 series from Park/Nelco Corporation, liquid crystalline polymer (LCP), such as LCP from Rogers Corporation or W. L. Gore & Associates, Inc., hydrocarbon composites, such as 4000 series from Rogers Corporation., and epoxy-based laminates, such as N4000 series from Park/Nelco Corp. For instance, examples include epoxy based N4000-13, bromine-free material laminated to LCP, organic layers with high K material, unfilled high-K organic layers, Rogers 4350, Rogers 4003 material, and other thermoplastic materials such as polyphenylene sulfide resins, polyethylene terephthalate resins, polybutylene terephthalate resins, polyethylene sulfide resins, polyether ketone resins, polytetraflouroethylene resins and graft resins, or similar low dielectric constant, low-loss organic material.

In some embodiments, the dielectric material may be a ceramic-filled epoxy. For example, the dielectric material may include an organic compound, such as a polymer (e.g., an epoxy) and may contain particles of a ceramic dielectric material, such as barium titanate, calcium titanate, zinc oxide, alumina with low-fire glass, or other suitable ceramic or glass-bonded materials. In some embodiments, the dielectric material may be an organic compound such as an epoxy (with or without ceramic mixed in, with or without fiberglass), popular as circuit board materials, or other plastics common as dielectrics. In these cases, the conductor is usually a copper foil which is chemically etched to provide the patterns. In still further embodiments, dielectric material may comprise a material having a relatively high dielectric constant (K), such as one of NPO (COG), X7R, X5R X7S, Z5U, Y5V and strontium titanate. In such examples, the dielectric material may have a dielectric constant that is greater than 100, for example within a range from between about 100 to about 4000, in some embodiments from about 1000 to about 3000.

Other materials may be utilized, however, including, N6000, epoxy based N4000-13, bromine-free material laminated to LCP, organic layers with high K material, unfilled high-K organic layers, Rogers 4350, Rogers 4003 material (from the Rogers Corporation), and other thermoplastic materials such as hydrocarbon, Teflon, FR4, epoxy, polyamide, polyimide, and acrylate, polyphenylene sulfide resins, polyethylene terephthalate resins, polybutylene terephthalate resins, polyethylene sulfide resins, polyether ketone resins, polytetraflouroethylene resins, BT resin composites (e.g., Speedboard C), thermosets (e.g., Hitachi MCL-LX-67F), and graft resins, or similar low dielectric constant, low-loss organic material.

Additionally, in some embodiments, non-organic dielectric materials may be used including a ceramic, semi-conductive, or insulating materials, such as, but not limited to, sapphire, ruby, alumina (Al₂O₃), aluminum nitride (AlN), beryllium oxide (BeO), aluminum oxide (Al₂O₃), boron nitride (BN), silicon (Si), silicon carbide (SiC), silica (SiO₂), silicon nitride (Si₃N₄), gallium arsenide (GaAs), gallium nitride (GaN), zirconium dioxide (ZrO₂), mixtures thereof, oxides and/or nitrides of such materials, or any other suitable ceramic material. Additional example ceramic materials include barium titanate (BaTiO₃), calcium titanate (CaTiO₃), zinc oxide (ZnO), ceramics containing low-fire glass, or other glass-bonded materials. Dielectric materials such as diamond and cubic boron arsenide may be used as well.

Suitable dielectric materials are generally electrically insulating and thermally conductive. For example, in some embodiments, the multilayer component may include a multilayer component substrate having a relatively high thermal conductivity, which may improve the device's power handling capabilities. For instance, the substrate can have a thermal conductivity that is greater than about 20 W/m·° C., in some embodiments greater than about 40 W/m·° C., in some embodiments greater than about 80 W/m·° C., and in some embodiments greater than about 100 W/m·° C.

As stated, the substrate comprises a plurality of dielectric layers formed from one or more dielectric materials as described above. It will be appreciated that the plurality of dielectric layers can provide stiffness or strength to the substrate, which can allow the substrate to be thinner while retaining sufficient stiffness and/or strength to maintain the structural integrity of the multilayer component. That is, the stack of layers provides the needed stiffness or strength while allowing the multilayer component as described herein to be thinner than typical or known components.

As used herein, “formed over,” may refer to a layer that is directly in contact with another layer. However, one or more intermediate layers or coatings may also be formed therebetween. For example, a conductive layer “formed over”a dielectric layer may refer to a conductive layer formed directly on the dielectric layer, or one or more intermediate layers or coatings may be formed between the conductive layer and the dielectric layer. Additionally, when used in reference to a bottom surface, “formed over” may be used relative to an exterior surface of the component. Thus, a layer that is “formed over” a bottom surface may be closer to the exterior of the component than the layer over which it is formed.

Each conductive layer comprises a conductive material. The conductive material of a respective conductive layer may be one or more of a variety of conductive materials. For example, the conductive material used to define the one or more conductive layers may include copper, nickel, gold, silver, or other metals or alloys.

The conductive layer(s) may be formed using a variety of suitable techniques. Subtractive, semi-additive or fully additive processes may be employed with panel or pattern electroplating of the conductive material followed by print and etch steps to define the patterned conductive layers. Photolithography, plating (e.g., electrolytic), sputtering, vacuum deposition, printing, or other techniques may be used to form the conductive layers. For example, a thin layer (e.g., a foil) of a conductive material may be adhered (e.g., laminated) to a surface of a dielectric layer. The thin layer of conductive material may be selectively etched using a mask and photolithography to produce a desired pattern of the conductive material on the surface of the dielectric material.

As previously described, in some embodiments the multilayer component may include a plurality of vias. The plurality of vias may be defined along the perimeter of the substrate of the multilayer component. For example, the plurality of vias may surround one or more conductive layers of the multilayer component. In some embodiments, the plurality of vias may be defined at regular intervals and may be described as a ring of vias. In other embodiments, the plurality of vias may be spaced apart at different intervals, which still may form a ring of vias or which may define another type of pattern or configuration of vias. For instance, in some embodiments, the perimeter of the multilayer component substrate has a generally rectangular shape including four sides, and in various embodiments, a portion of the plurality of vias may be defined along each of the four sides of the perimeter, along two of the four sides of the perimeter, or in some other configuration.

As previously stated, the one or more conductive layers may include an outer conductive layer or shield layer formed over an outer dielectric layer of the plurality of dielectric layers. The shield layer can be formed over the outer dielectric layer such that the shield layer is formed over the perimeter of the substrate and contacts the plurality of vias. The plurality of vias may be electrically connected to ground such that the shield layer forms a shield for the multilayer component.

The vias may be formed by drilling (e.g., mechanical drilling, laser drilling, etc.) through holes and plating or filling the through holes with a conductive material, for example, using electroless plating or seeded copper. The conductive materials may include, e.g., copper, nickel, gold, silver, or other metals or alloys. In some embodiments, one or more of the plurality of vias may be filled with conductive material such that a solid column of conductive material is formed. Alternatively, or additionally, the interior surface of one or more of the plurality of vias may be plated such that one or more vias are hollow but are lined with conductive material.

In some embodiments, the multilayer component includes a cover. The cover is one or more layers of material that are in addition to the plurality of dielectric layers and the plurality of conductive layers that form the multilayer component substrate. For example, the cover may be formed over the top of the multilayer component substrate and/or over one or more sides of the multilayer component substrate that extend between the top and the bottom of the multilayer component substrate.

The cover can provide stiffness to the multilayer component, which can improve the utility or usability of the multilayer component. Further, the cover may be electrically isolative and thermally conductive, e.g., to conduct heat away from the multilayer component for heat or thermal management. The cover may be formed from, e.g., aluminum nitride (AlN), alumina (Al₂O₃), beryllium oxide (BeO), diamond, or other suitable electrically insulative, thermally conductive material such as the ceramics and the like described elsewhere herein.

As previously described, the multilayer component includes at least one conductive layer. In some embodiments, at least two conductive layers are formed over two different dielectric layers of the plurality of dielectric layers such that the at least two conductive layers are positioned at different locations along the Z-direction. In other embodiments, three, four, or more conductive layers are formed over different dielectric layers. In still other embodiments, two or more separate conductive elements, each formed from a conductive material such as those described herein, may be formed over a single dielectric layer. For instance, a first conductive element and a second conductive element, which is spaced apart from the first conductive element, may be formed over the same dielectric layer. The multiple conductive elements formed over a respective dielectric layer may collectively be referred to as a conductive layer.

The plurality of dielectric layers, including the one or more conductive layers formed over one or more of the dielectric layers of the plurality of dielectric layers, may be stacked along the Z-direction. In some embodiments, when stacked, one or more conductive layers may be positioned at a location along the Z-direction such that the one or more conductive layers are sandwiched in the remaining dielectric layers. For example, in a multilayer component including two conductive layers overlapping to form a capacitor and spaced apart from one another along the Z-direction, a first plurality of dielectric layers having a first thickness may be positioned below the second conductive layer along the Z-direction, and a second plurality of dielectric layers having a second thickness may be positioned above the first conductive layer along the Z-direction. In such embodiments, the first plurality of dielectric layers may define the bottom of the component substrate, and the second plurality of dielectric layers may define the top of the component substrate. A third plurality of dielectric layers having a third thickness may be positioned between the first conductive layer and the second conductive layer along the Z-direction.

The shield layer may be positioned on top of the second plurality of dielectric layers such that the one or more conductive layers described above are sandwiched in the dielectric layers and the shield layer is positioned on top of the dielectric layers. In some embodiments, an outer layer, such as a solder mask, a layer of dielectric material, or the like, may be disposed over the shield layer such that the outer layer defines the top of the component substrate. The outer layer may form a cover of the multilayer component. In other embodiments not including the outer layer, the shield layer may define the top of the multilayer component substrate, and the first plurality of dielectric layers may define the bottom of the multilayer component substrate. In still other embodiments, rather than defining the top of the multilayer component, the shield layer or the outer layer may define the bottom of the multilayer component, e.g., whether the shield layer or the outer layer is the top or the bottom of the multilayer component may depend on the mounting orientation of the multilayer component.

In some embodiments, the multilayer component includes a resistive layer. The resistive layer can be formed over a respective one dielectric layer and disposed in the stack of layers between the conductive layers and the shield layer. The resistive layer can be disposed relatively nearer the shield layer than the other conductive layers, e.g., in one embodiment, a relatively thin dielectric segment is disposed between the shield layer and the resistive layer. The relatively thin dielectric segment can be a single dielectric layer or a plurality of dielectric layers having a thickness in the Z-direction that is less than or equal to a maximum dielectric segment thickness (i.e., no greater than the maximum dielectric segment thickness). The other conductive layers of the multilayer component, such as the first conductive layer, the first and second conductive layers, etc. described herein, may be disposed at or near the middle or center of the stack of layers. For example, the shield layer and the resistive layer may be disposed at or near an outer surface of the multilayer component (such as the top or bottom of the multilayer component as described herein) while the remaining conductive layers may be disposed at or near the middle or center of the multilayer component, with the resistive layer disposed between the shield layer and the other conductive layers but relatively near the shield layer. In other embodiments, a conductive layer defining an inductor can be positioned in the stack of layers relatively near the resistive layer rather than at or near the middle or center of the stack of layers.

Other placements or arrangements of the resistive layer and the other conductive layers are contemplated as well.

It will be appreciated that the resistive layer can have any suitable shape, e.g., to achieve a desired performance value. For instance, the resistive material forming the resistive layer can be rectangular in shape or can be looped, coiled, or generally snake shaped. Of course, other shapes for the resistive layer may be used as well.

In some embodiments, the multilayer component is a capacitor. For example, the one or more conductive layers formed over respective dielectric layers can include a first conductive layer formed over a first dielectric layer of the plurality of dielectric layers and a second conductive layer formed over a second dielectric layer of the plurality of dielectric layers. The second conductive layer overlaps the first conductive layer in an X-direction and a Y-direction to form an overlap area. The X-direction and the Y-direction are perpendicular to one another and are each perpendicular to the Z-direction. In some embodiments, the multilayer capacitor includes a plurality of first conductive layers and a plurality of second conductive layers, which are stacked with the plurality of dielectric layers that do not have a conductive layer formed thereover.

In still other embodiments, the first and second conductive layers do not overlap and the multilayer capacitor includes one or more floating electrodes that overlap the first conductive layer and the second conductive layer to form two overlapping areas in an X-Y plane defined by the X-direction and the Y-direction. For instance, the first conductive layer can extend from a first end of the multilayer capacitor, and in the same plane as the first conductive layer, the second conductive layer can extend from a second end of the multilayer capacitor that is opposite the first end. A floating electrode spaced apart from the first and second conductive layers in the Z-direction can overlap the end of the first conductive layer that is adjacent the second conductive layer, as well as overlap the end of the second conductive layer that is adjacent the first conductive layer. It will be appreciated that the two overlapping areas can define two capacitors within the single multilayer capacitor package. Further, in some embodiments, the multilayer capacitor includes a plurality of first conductive layers stacked in a first set and a plurality of second conductive layers stacked in a second set, with a plurality of floating electrodes alternately stacked between each pair of planar first and second conductive layers.

The one or more first conductive layers of the multilayer capacitor are electrically connected to a first terminal, and the one or more second conductive layers are electrically connected to a second terminal. For example, a first via can 12 extend from the first conductive layer to a first terminal disposed on a top surface or a bottom surface of the multilayer capacitor, and a second via can extend from the second conductive layer to a second terminal disposed on the top surface or the bottom surface of the multilayer capacitor. In other embodiments, one or both of the first terminal and the second terminal may be disposed on a side surface of the multilayer capacitor, with the first via and/or the second via extending to the first terminal and/or second terminal defined on such side surface. Alternatively, a tab of conductive material can extend from the respective conductive layer to the respective terminal disposed on the side surface, or an end of the respective conductive layer can extend to the respective terminal disposed on the side surface. It will be appreciated that the multilayer capacitor can include four side surfaces extending between the top surface and the bottom surface; two of the four side surfaces also may be referred to as end surfaces and may be spaced apart from one another along the longitudinal or X-direction while the remaining side surfaces are spaced apart from one another along the lateral or Y-direction.

In some embodiments, the multilayer component is an inductor having a signal path that includes an input and an output. For instance, a conductive material may be formed over a first dielectric layer of the plurality of dielectric layers of the substrate of the multilayer inductor to form a first conductive layer and define the signal path. That is, the conductive material of the conductive layer is in a shape that defines the signal path. For example, the signal path may form a loop or a partial loop, e.g., the signal path may extend a full 360° about a central point or may extend over only a portion of a 360° path about the central point, such as about 340°, about 315°, about 300°, about 180°, about 135°, about 90°, or less. To form a loop or a partial loop, the signal path may include one or more corners. Each corner may have an angle greater than about 15 degrees, in some embodiments greater than about 30 degrees, in some embodiments greater than about 45 degrees, and in some embodiments greater than about 60 degrees (e.g., about 90 degrees). In some embodiments, the signal path has from one to twenty corners, such as ten corners, but in other embodiments, the signal path may have more than twenty corners. In some embodiments, the signal path may have fewer than six corners, in some embodiments fewer than four corners, in some embodiments fewer than three corners, and in some embodiments fewer than two corners. In some embodiments, the signal path may be free of any corners. As stated, the signal path may define a full loop or less, e.g., the signal path may define a full loop (a full 360° path about a central point) or less than one half of a loop (less than a 180° path about the central point).

In some embodiments, the signal path shaped in a loop or a partial loop is formed entirely on a single layer. However, in other embodiments, whether formed as a loop, a partial loop, or other shape (such as one or more straight lines), the signal path can respectively include at least two conductive layers spaced apart from each other in the Z-direction of the multilayer component and connected by one or more vias. For instance, a first portion of the signal path, including the input, may be defined on a first conductive layer, and a second portion of the signal path, including the output, may be defined on a second conductive layer, with at least one via extending between the first portion and the second portion to connect the two portions of the signal path.

Additionally, or alternatively, in some embodiments, the multilayer inductor comprises multiple inductive elements. For example, a first portion of the signal path may be formed on a first conductive layer, a second portion of the signal path may be formed on a second conductive layer, a third portion of the signal path may be formed on a third conductive layer, etc., with each of the first, second, third, or more portions of the signal path being formed as a loop, a partial loop, or other shape. The various signal path portions may be connected by a respective via extending between respective conductive layers that are adjacent to one another along the Z-direction. For instance, in an embodiment comprising four portions of the signal path formed as four separate conductive layers deposited over four separate dielectric layers, a first via extends between the first conductive layer and the second conductive layer to electrically connect the first portion of the signal path and the second portion of the signal path, a second via extends between the second conductive layer and the third conductive layer to electrically connect the second portion of the signal path and the third portion of the signal path, and a third via extends between the third conductive layer and the fourth conductive layer to electrically connect the third portion of the signal path and the fourth portion of the signal path. Each of the first via, the second via, and the third via extend along the Z-direction between the respective conductive layers. It will be appreciated that each of the first portion, the second portion, the third portion, and the fourth portion of the exemplary signal path may have the same shape or at least one portion may have a different shape. For example, one or more of the first, second, third, or fourth portions may be formed in a loop having three or more corners, and each of the first, second, third, and fourth portions may have the same number of corners or at least one portion may have a different number of corners. In some embodiments, the number of signal path portions and/or the respective shapes of the signal path portions may be selected to achieve a desired inductance. It will be appreciated that the number and shapes of the signal path portions described herein are by way of example only; in various embodiments, a multilayer component can include at least one inductor having at least one signal path portion, e.g., a single inductive element formed over a single layer or multiple inductive elements formed over multiple layers, such as two, three, four, eight, twelve, or more inductive elements that are each conductive layers formed over separate dielectric layers.

The input and the output of the signal path can be connected to external terminals. In some embodiments, an input contact pad is defined on the bottom of the substrate of the multilayer inductor, and an output contact pad is defined on the bottom of the substrate of the multilayer inductor. In such embodiments, at least one contact pad via electrically connects the input of the signal path with the input contact pad, and at least one contact pad via electrically connects the output of the signal path with the output contact pad. In other embodiments, at least one of the input signal pad or the output signal pad is defined on the top of the multilayer inductor substrate, and in still other embodiments, at least one of the input signal pad or the output signal pad is defined on a side surface of the multilayer inductor substrate, with the side surfaces of the multilayer inductor substrate extending between the top and bottom of the substrate as described above.

In some embodiments, the multilayer component is a filter including a conductive layer forming a signal path having an input and an output. The signal path of the filter can include a plurality of elements, such as resonators or the like or one or more capacitors and one or more inductors connected to form a filter, formed from the conductive material of one or more conductive layers. The filter may be configured as one of a variety of suitable filter types, including, for example, a low pass filter, a high pass filter, or a bandpass filter. The filter may have a characteristic frequency (e.g., a low pass frequency, high pass frequency, an upper bound of a band pass frequency, or a lower bound of a band pass frequency (e.g., a stop band frequency)) that ranges from about 100 MHz to about 5 GHz, or higher, such as about 10 GHz, about 20 GHz, about 30 GHz, about 50 GHz, or higher. In some embodiments, the filter may have a characteristic frequency that ranges from about 150 MHz to about 4 GHz, and in some embodiments from about 200 MHz to about 3 GHz. The characteristic frequency of the filter may have other ranges as well.

The types of multilayer components described herein are by way of example only and are not intended to be a complete or exhaustive list of multilayer components that can include the substrate structure and shielding as described herein. That is, while the multilayer component could be a capacitor, an inductor, or a filter as described herein, the multilayer component also could be another type of component not explicitly described herein. In still other embodiments, the multilayer component includes two or more types of components, such as a multilayer component that includes both a capacitor and an inductor.

A multilayer component as described herein may be incorporated into an assembly. In some embodiments, an assembly may include a device and a multilayer component as described herein. The device may include a device substrate and a ground defined on the device substrate. The multilayer component may be attached to the device substrate, e.g., on an outer or mounting surface of the device substrate or embedded within the device substrate along the Z-direction such that the multilayer component is spaced apart from the mounting surface along the Z-direction. The device substrate may be, e.g., a printed circuit board (PCB) or the like formed from any suitable material.

In some embodiments, the mounting surface of the device may extend in a mounting plane parallel to an X-Y plane. The plurality of dielectric layers (and the at least one conductive layer formed over a dielectric layer of the plurality of dielectric layers) of the multilayer component may each extend in parallel to a plane that extends in a longitudinal direction and a lateral direction. In some embodiments, the plane may be parallel to the X-Y plane such that the multilayer component is attached to the device with the plurality of dielectric layers extending parallel to the mounting surface. In other embodiments, the multilayer component may be attached to the device such that the plurality of dielectric layers extend perpendicular to the mounting surface.

As described herein, the multilayer component defines a plurality of vias extending from a shield layer. In such embodiments, one or more of the vias may be electrically connected to the ground defined on the device substrate. As such, the vias and shield layer may form a grounded shield for the multilayer component, which can provide protection from interference. For instance, the plurality of vias may extend between the shield layer and a ground terminal disposed on a surface of the multilayer component substrate, and the ground terminal may be electrically connected to the ground defined on the device substrate, e.g., through a via or the like. The plurality of vias may be electrically connected to the ground of the device in other ways as well.

It will be appreciated that one or more other conductive layers may be connected to one or more ports or other conductive pads of the device. For example, where the multilayer component is a multilayer capacitor having a first terminal electrically connected to one or more first conductive layers and a second terminal electrically connected to one or more second conductive layers, the first terminal can be electrically connected to a first device terminal and the second terminal can be electrically connected to a second device terminal. Similarly, where the multilayer component is a multilayer inductor having a first terminal or input contact pad electrically connected to an input of a signal path and a second terminal or output contact pad electrically connected to an output of the signal path, the first terminal can be electrically connected to a first device terminal and the second terminal can be electrically connected to a second device terminal. In at least some embodiments, the first and second device terminals can be defined on the mounting surface of the device substrate.

The present subject matter also includes methods for forming multilayer components and methods for forming assemblies as described herein. As one example, a method for forming a multilayer component may include forming a plurality of dielectric layers; forming at least one conductive layer over a dielectric layer; and stacking the plurality of dielectric layers in a Z-direction to form a substrate. In some embodiments, the method also includes forming at least one external terminal that is electrically connected to the at least one conductive layer. In embodiments of forming assemblies, the at least one external terminal can be electrically connected to a device of the assembly.

In some embodiments, the multilayer component may generally be compact. For example, the multilayer component may have a length that is less than about 150 mm, in some embodiments less than about 100 mm, in some embodiments less than about 80 mm, in some embodiments less than about 50 mm, in some embodiments less than about 30 mm, in some embodiments less than about 15 mm, in some embodiments less than about 8 mm, in some embodiments less than about 5 mm, and in some embodiments less than about 1 mm. Further, the multilayer component may have a width that is less than about 100 mm, in some embodiments less than about 60 mm, in some embodiments less than about 40 mm, in some embodiments less than about 20 mm, in some embodiments less than about 15 mm, in some embodiments less than about 10 mm, in some embodiments less than about 5 mm, in some embodiments less than about 3 mm, and in some embodiments less than about 1 mm.

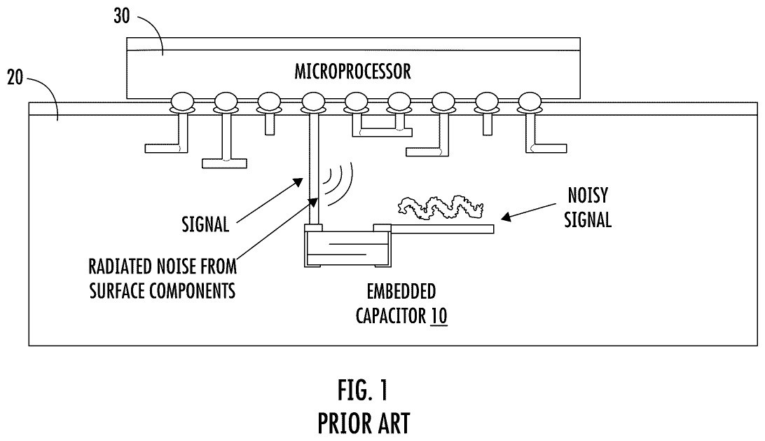

Referring now to the figures, FIG. 1 provides a schematic cross-sectional view of an embedded capacitor 10 according to the prior art. As shown in FIG. 1, known capacitors embedded in a device substrate 20, such as a printed circuit board (PCB) on which is mounted a microprocessor 30, are subjected to noise that can impact their performance. That is, known capacitor designs are subject to electromagnetic (EM) influence from and to surrounding parts and/or ground planes. For example, as illustrated in FIG. 1, radiated noise from surface components can intersect the embedded capacitor 10 and result in a noisy signal from the capacitor 10. Other components, such as inductors, filters, varistors, etc., can also suffer from and contribute to noise of surrounding parts and/or ground planes, particularly when embedded in a manner similar to the capacitor 10 of FIG. 1.

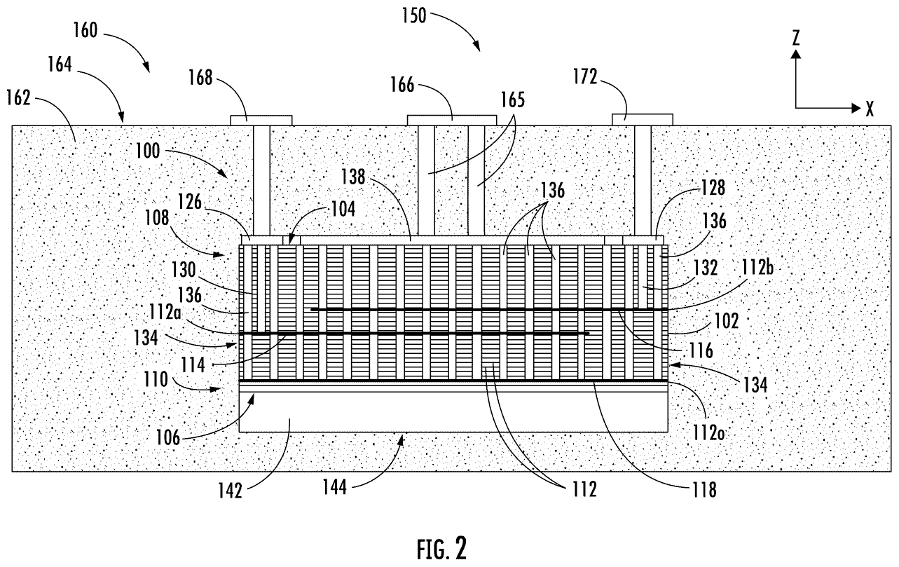

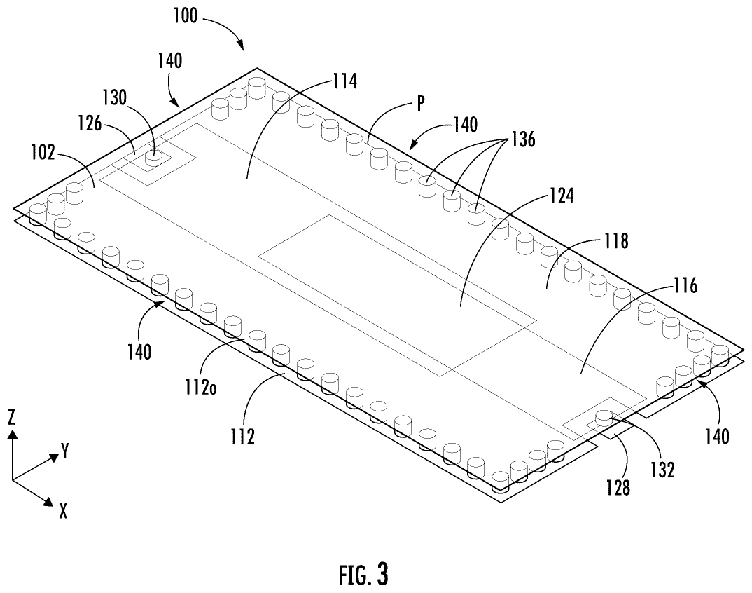

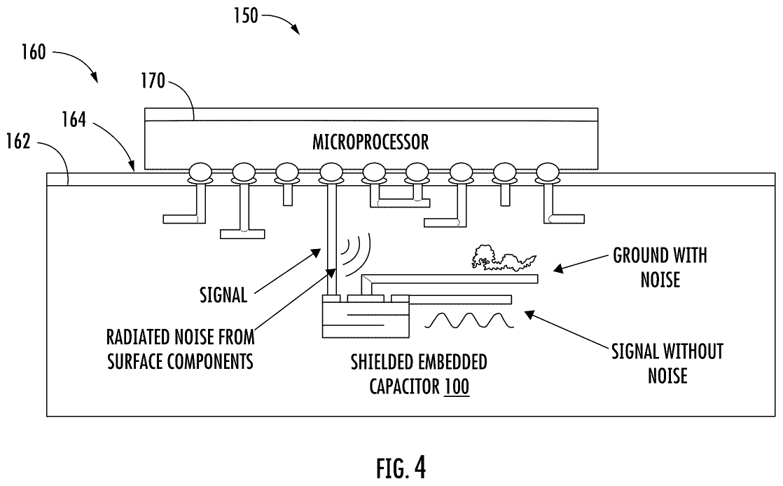

FIG. 2 provides a schematic cross-sectional view of an assembly 150 including a multilayer component 100 embedded in a device 160, according to the present disclosure. FIG. 3 provides a top perspective view of the multilayer component 100. It will be appreciated that various elements in FIG. 3 are shown as transparent to depict, e.g., any conductive patterns disposed on layers sandwiched within the stack of layers forming the multilayer component 100; also, other elements of the multilayer component 100 shown in FIG. 2 may be omitted in FIG. 3 for purposes of illustration. FIG. 4 provides another schematic cross-sectional view of the multilayer component 100 embedded in the device 160, with schematic indications of the contrast between the present disclosure and the prior art capacitor depicted in FIG. 1.

As shown in FIG. 2, the multilayer component 100 includes a component substrate 102 defining an upper surface 104 and a lower surface 106 opposite the upper surface 104 along a vertical Z-direction. The upper surface 104 extends in a first plane parallel to an X-Y plane defined by a longitudinal X-direction and a lateral Y-direction. The lower surface 106 of the multilayer component 100 extends in a second plane parallel to the X-Y plane. As such, the first plane and the second plane are parallel to one another as well as to the X-Y plane. In the embodiment of FIG. 2, the upper surface 104 is defined at a top 108 of the multilayer component 100, and the lower surface 106 is defined at a bottom 110 of the multilayer component 100. It will be appreciated that the X-direction and the Y-direction are perpendicular to one another and are each perpendicular to the Z-direction.

The component substrate 102 includes a plurality of dielectric layers 112, including an outer dielectric layer 1120. A first conductive layer 114 is formed over a first dielectric layer 112a of the plurality of dielectric layers 112, and a second conductive layer 116 is formed over a second dielectric layer 112b of the plurality of dielectric layers 112. A shield layer 118 is formed over the outer dielectric layer 1120.

As described elsewhere herein, the plurality of dielectric layers 112 may be formed from one or more of a variety of dielectric materials, such as organic, ceramic, and/or other dielectric materials. Similarly, each of the first conductive layer 114, the second conductive layer 116, and the shield layer 118 is formed from one or more of a variety of conductive materials, such as metals, metal alloys, and/or other conductive materials, disposed on the first dielectric layer 112a, the second dielectric layer 112b, and the outer dielectric layer 112o, respectively, using any suitable process, such as one or more of the exemplary processes described above for depositing conductive material on a dielectric material.

As shown in FIG. 2, the plurality of dielectric layers 112 are stacked in the Z-direction to form the component substrate 102. The component substrate 102 has a top 108 and a bottom 110. The first conductive layer 114 and the second conductive layer 116 are stacked in the component substrate 102 such that the conductive layers 114, 116 are spaced apart from one another along the Z-direction. That is, one or more dielectric layers 112 are disposed between the first conductive layer 114 and the second conductive layer 116. Similarly, the first conductive layer 114 and the second conductive layer 116 are stacked in the component substrate 102 such that the conductive layers 114, 116 are spaced apart from both the top and the bottom of the component substrate 102, with dielectric layers 112 disposed between the conductive layers 114, 116 and the top 108 of the component substrate 102 and between the conductive layers 114, 116 and the bottom 110 of the component substrate 102.

Referring to FIGS. 2 and 3, the first and second conductive layers 114, 116 overlap to form a capacitor, such that the multilayer component 100 is a multilayer capacitor. More particularly, the second conductive layer 116 overlaps the first conductive layer 114 in the X-direction and the Y-direction to form an overlap area 124. In some embodiments, the multilayer component 100 includes a plurality of first conductive layers 114 that are alternately stacked in the Z-direction with a plurality of second conductive layers 116 such that each first conductive layer 114 overlaps at least one second conductive layer 116. In still other embodiments, a first conductive layer 114 may be co-planar with a second conductive layer 116, i.e., conductive material is disposed on a single dielectric layer 112 to form both the first conductive layer 114 and the second conductive layer 116 over the same dielectric layer 112, and the multilayer component 100 may also include a floating conductive layer that overlaps the first conductive layer 114 and the second conductive layer 116 to form two capacitors within a single multilayer component package.

The first conductive layer 114 is electrically connected to a first terminal 126, and the second conductive layer 116 is electrically connected to a second terminal 128. In embodiments containing a plurality of first conductive layers 114 and a plurality of second conductive layers 116, each first conductive layer 114 is electrically connected to the first terminal 126, and each second conductive layer 116 is electrically connected to the second terminal 128.

The conductive layers 114, 116 can be electrically connected to the respective terminal using a terminal via. For example, as shown in FIGS. 2 and 3, a first terminal via 130 extends from the first conductive layer 114 to the first terminal 126, and a second terminal via 132 extends from the second conductive layer 116 to the second terminal 128. In embodiments containing a plurality of first conductive layers 114 and a plurality of second conductive layers 116, the first terminal via 130 can connect each first conductive layer 114 with the first terminal 126, and the second terminal via 132 can connect each second conductive layer 116 with the second terminal 128.

The first terminal 126 and the second terminal 128 can be disposed on various outer surfaces of the component substrate 102. As depicted in FIG. 2, the first terminal 126 and the second terminal 128 are each disposed on the upper surface 104 of the component substrate 102. More particularly, the first terminal 126 and the second terminal 128 are disposed on the surface of the component substrate 102 that is opposite the shield layer 118 along the Z-direction. In FIG. 3, the first terminal 126 and the second terminal 128 are also disposed opposite the shield layer 118 along the Z-direction, but the multilayer component 100 is flipped from its orientation in FIG. 2 such that the shield layer 118 is shown at the top 108 of the multilayer component 100 rather than the bottom 110 as shown in FIG. 2. Thus, it will be appreciated that the first terminal 126 and the second terminal 128 can be disposed on either the upper surface 104 or the lower surface 106 of the component substrate 102. The designation of what is the upper surface 104 and the lower surface 106 may depend on the orientation of the multilayer component 100 for mounting on or in a device 160, e.g., whether the multilayer component 100 is embedded or surface mounted, the location of connections to the device 160, etc.

Alternatively, or additionally, at least one of the first terminal 126 or the second terminal 128 may be defined on a side surface of the component substrate 102. The component substrate 102 may have any suitable shape, such as a rectangular parallelopiped shape. It will be appreciated that, in such embodiments, the component substrate 102 includes four side surfaces 134 extending between the upper surface 104 and the lower surface 106. Two of such side surfaces 134, e.g., the side surfaces 134 opposite one another along the longitudinal X-direction, may also be referred to as end surfaces. In some embodiments, at least one of the first terminal 126 or the second terminal 128 may be disposed on a side surface 134 of the component substrate 102, with the respective terminal via 130, 132 extending to the respective terminal disposed on the side surface 134 or with another type of electrical connection, such as a tab of the respective conductive layer 114, 116, extending between the respective conductive layer 114, 116 and the respective terminal 126, 128.

Further, a plurality of vias 136 extends from the shield layer 118 toward the opposite surface of the component substrate 102. As shown in FIG. 2, a ground terminal 138 is defined on the upper surface 104 of the component substrate 102, and each via 136 of the plurality of vias 136 extends from the shield layer 118 to the ground terminal 138. The ground terminal 138 is electrically connected to a ground 166 of the device 160, e.g., through one or more ground vias 165. In some embodiments, for instance where the multilayer component 100 is surface mounted instead of embedded, the multilayer component 100 may not include a ground terminal 138 but the vias 136 may extend to an outer surface of the component substrate 102 (e.g., the upper surface 104 or the lower surface 106) and, e.g., directly contact the ground 166 of the device 160 when the multilayer component 100 is mounted on the mounting surface 164 of the device 160.

As shown in FIG. 3, the component substrate 102 defines a perimeter P. The plurality of vias 136 may be defined along the perimeter P of the component substrate 102. The component substrate 102 may have any suitable shape, such as a rectangular parallelopiped shape in which the perimeter P of the component substrate 102 has a generally rectangular shape in an X-Y plane, including four sides 140. As depicted in FIG. 3, a portion of the plurality of vias 136 may be defined along each of the four sides 140 of the perimeter P.

However, whether formed along each of the four sides 140 of a rectangular perimeter P or otherwise disposed along a perimeter P of any suitable shape, the plurality of vias 136 may surround the first conductive layer 114 and the second conductive layer 116 of the multilayer component 100 in the X-direction and the Y-direction. In some embodiments, the plurality of vias 136 are defined at regular intervals, and in other embodiments, the plurality of vias 136 are irregularly spaced apart from one another. Whether or not regularly spaced, the plurality of vias 136 disposed about the entire perimeter P may be described as a ring of vias 136, e.g., the plurality of vias 136 ring the multilayer component 100. Further, as illustrated in FIG. 3, the shield layer 118 is formed over the outer dielectric layer 1120 such that the shield layer 118 is formed over the perimeter P of the component substrate 102 and in contact with the plurality of vias 136. As such, the shield layer 118 and the plurality of vias 136 electrically connected thereto surround the first conductive layer 114 and the second conductive layer 116.

Each via 136 of the plurality of vias 136 extends from the shield layer 118 to the surface of the component substrate 102 opposite the shield layer 118 along the Z-direction, e.g., the upper surface 104 in the embodiment of FIG. 2. At least one via 136 of the plurality of vias 136 may be a through hole filled with conductive material such that a solid column of conductive material is formed, or at least one via 136 of the plurality of vias 136 may be a through hole having the interior surfaces thereof plated with conductive material such that the via(s) 136 are hollow. In various embodiments, each of the vias 136 may be filled; each of the vias 136 may be plated, hollow vias; or a mix of filled and plated, hollow vias 136 may be used. Exemplary conductive materials and methods for forming the via through holes are described elsewhere herein. Further, the various other vias described herein, such as the first terminal vias 130, second terminal vias 132, and ground vias 165, can also be filled vias or plated, hollow vias.

As described herein, the grounded shield layer 118 and plurality of vias 136 form a cage-like grounded shield of the multilayer component 100. For example, as previously described, the plurality of vias 136 can be disposed along the perimeter P of the multilayer component 100 such that the plurality of vias 136 surround the first conductive layer 114 and the second conductive layer 116, or the capacitive portion of the multilayer component 100 illustrated in FIGS. 2 and 3.

Referring to FIG. 4, such grounded shield layer 118 and plurality of vias 136 provide protection from interference for the multilayer component 100, such as from electromagnetic interference radiated from nearby components, and/or may improve performance compared to capacitors lacking a shield.

Referring to FIG. 2, in some embodiments, the multilayer component 100 includes a cover 142, which may be, e.g., one or more layers of material that are in addition to the plurality of dielectric layers 112 and the conductive layers 114, 116 that form the component substrate 102. A total thickness tₜₒₜₐₗ of the multilayer component 100 in the Z-direction includes a thickness t of the component substrate 102 and a thickness t_{c} of the cover 142. For example, in FIG. 2, the total thickness tₜₒₜₐₗ of the multilayer component 100 is defined in the Z-direction between the upper surface 104 of the component substrate 102 and an outer surface 144 of the cover 142. The thickness t_{c} of the cover 142 may be about 1000 μm or less, such as within a range of about 100 μm to about 1000 μm, a range of about 200 μm to about 800 μm, a range of about 300 μm to about 700 μm, or a range of about 400 μm to about 600 μm. The total thickness tₜₒₜₐₗ may be about 2000 μm or less, such as about 1500 μm or less, such as about 1250 μm or less, such as about 1000 μm or less, such as about 800 μm or less. The cover 142 may be formed from one or more of a variety of materials as described in greater detail elsewhere herein.

Keeping with FIG. 2, the multilayer component 100 is incorporated into an assembly 150 including the device 160. The device 160 has a device substrate 162 having a mounting surface 164, and the device 160 also includes a ground 166 as discussed above. The ground 166 may be disposed on the mounting surface 164 of the device substrate 162 or may be located within the device substrate 162. Other ports or terminals, such as an input signal terminal 168, may be disposed on the mounting surface 164, as well as one or more components, such as the microprocessor 170 shown in FIG. 4. The device substrate 162 may be, e.g., a printed circuit board (PCB) or the like formed from any suitable material.

In the embodiment of FIG. 2, as well as FIG. 4, the multilayer component 100 is attached to the device 160 such that the multilayer component 100 is embedded in the device substrate 162. However, in other embodiments, the multilayer component 100 may be attached to the device substrate 162, e.g., on the mounting surface 164 of the device substrate 160 such that the multilayer component 100 is a surface mounted component. Further, in some embodiments, the multilayer component 100 may be partially embedded in the device substrate 162 rather than fully embedded in the device substrate 162 as shown in FIGS. 2 and 4. For instance, at least a portion of the multilayer component 100 may extend above or beyond the device substrate 162 along the Z-direction.

As depicted in FIG. 2, the mounting surface 164 of the device 160 extends in a mounting plane parallel to an X-Y plane defined by the X-direction and the Y-direction. The plurality of dielectric layers 112, as well as the first conductive layer 114, second conductive layer 116, and shield layer 118 formed over respective dielectric layers 112, of the multilayer component 100 each extend in the X-direction and the Y-direction parallel to the X-Y plane such that the multilayer component 100 is embedded in the device 160 with the plurality of dielectric layers 112, the first conductive layer 114, the second conductive layer 116, and the shield layer 118 extending parallel to the mounting surface 164 of the device 160.

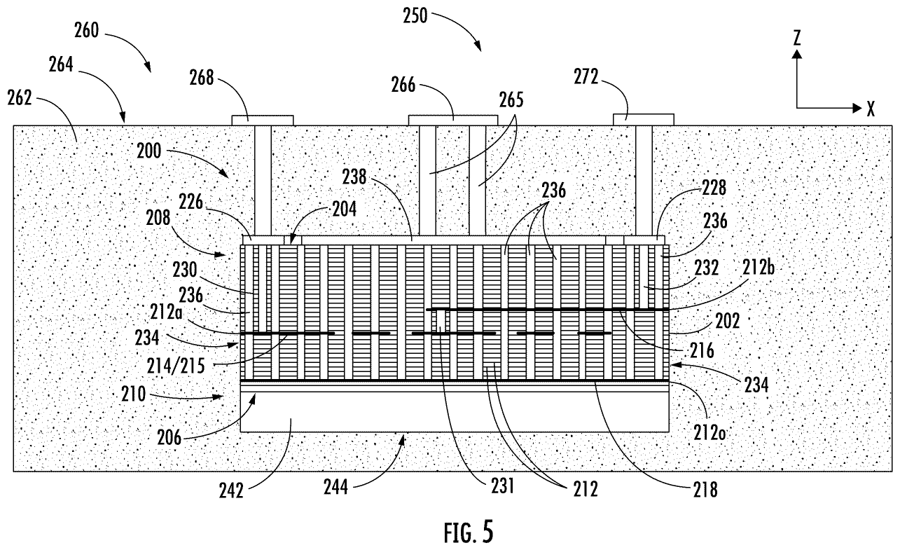

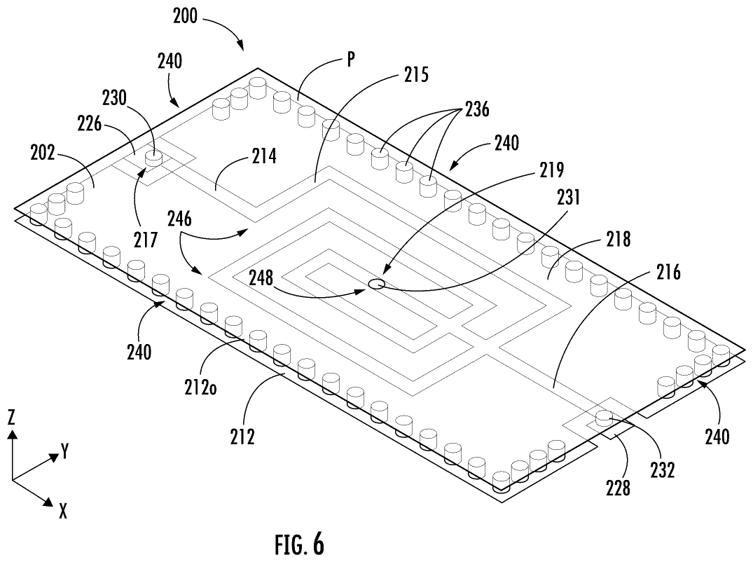

Turning now to FIGS. 5 and 6, another embodiment of a multilayer component is provided, in which the illustrated multilayer component 200 is a multilayer inductor rather than a capacitor as shown in FIGS. 2, 3, and 4. It will be appreciated that the multilayer component 200 may be substantially similar to the multilayer component 100 described above, with only changes to the arrangement of the conductive layer(s) to define an inductor rather than a capacitor. Accordingly, the use of similar reference characters in FIGS. 5 and 6 will be understood to indicate the same or similar features as those illustrated in FIGS. 2, 3, and 4.

FIG. 5 provides a schematic cross-sectional view of an assembly 250 including a multilayer component 200 embedded in a device 260, according to the present disclosure. FIG. 6 provides a top perspective view of the multilayer component 200. It will be appreciated that various elements in FIG. 6 are shown as transparent to depict, e.g., any conductive patterns disposed on layers sandwiched within the stack of layers forming the multilayer component 200; also, other elements of the multilayer component 200 shown in FIG. 5 may be omitted in FIG. 6 for purposes of illustration.

Referring to FIG. 5, the multilayer component 200 includes a component substrate 202 defining an upper surface 204 and a lower surface 206 opposite the upper surface 204 along a vertical Z-direction. The upper surface 204 extends in a first plane parallel to an X-Y plane defined by a longitudinal X-direction and a lateral Y-direction. The lower surface 206 of the multilayer component 200 extends in a second plane parallel to the X-Y plane. As such, the first plane and the second plane are parallel to one another as well as to the X-Y plane. In the embodiment of FIG. 5, the upper surface 204 is defined at a top 208 and the lower surface 206 is defined at a bottom 210 of the multilayer component 200. It will be appreciated that the X-direction and the Y-direction are perpendicular to one another and are each perpendicular to the Z-direction.

The component substrate 202 includes a plurality of dielectric layers 212, including an outer dielectric layer 2120. A first conductive layer 214 is formed over a first dielectric layer 212a of the plurality of dielectric layers 212, and a second conductive layer 216 is formed over a second dielectric layer 212b of the plurality of dielectric layers 212. A shield layer 218 is formed over the outer dielectric layer 212o.

As shown most clearly in FIG. 6, the first conductive layer 214 defines a signal path 215. The signal path 215 comprises an input 217 and an output 219. Like the first conductive layer 114 of the multilayer component 100, the first conductive layer 214 of the multilayer component 200 is formed from conductive material deposited on a respective one dielectric layer 212 of the plurality of dielectric layers 212.

The input 217 is electrically connected to an input contact pad 226, and the output 219 is electrically connected to an output contact pad 228. It will be appreciated that the input contact pad 226 and the output contact pad 228 are external terminals of the multilayer component 200 similar to the first terminal 126 and the second terminal 128 of the multilayer component 100. The input contact pad 226 and the output contact pad 228 can be disposed on various outer surfaces of the component substrate 202. As depicted in FIG. 5, the input contact pad 226 and the output contact pad 228 are each disposed on the upper surface 204 of the component substrate 202. More particularly, the input contact pad 226 and the output contact pad 228 are disposed on the surface of the component substrate 202 that is opposite the shield layer 218 along the Z-direction. In FIG. 6, the input contact pad 226 and the output contact pad 228 are also disposed opposite the shield layer 218 along the Z-direction, but the multilayer component 200 is flipped from its orientation in FIG. 5 such that the shield layer 218 is shown at the top 208 of the multilayer component 200 rather than the bottom 210 as shown in FIG. 5. Thus, it will be appreciated that the input contact pad 226 and the output contact pad 228 can be disposed on either the upper surface 204 or the lower surface 206 of the component substrate 202. The designation of what is the upper surface 204 and the lower surface 206 may depend on the orientation of the multilayer component 200 for mounting on or in a device 260, e.g., whether the multilayer component 200 is embedded or surface mounted, the location of connections to the device 260, etc. Alternatively, or additionally, at least one of the input contact pad 226 or the output contact pad 228 may be defined on a side surface of the component substrate 202, such as described with respect to the first terminal 126 and second terminal 128 of the multilayer component 100.

The input 217 and the output 219, and thus the conductive layers 214, 216, can be electrically connected to the respective contact pad using a contact pad via. For example, as shown in FIGS. 5 and 6, a first contact pad via 230 extends from the input 217 and the first conductive layer 214 to the input contact pad 226, and a second contact pad via 232 extends from the second conductive layer 216 to the output contact pad 228. A connecting via 231 extends from the output 219 to the second conductive layer 216 to connect the output 219 to the output contact pad 228. That is, through the connecting via 231 and the second contact pad via 232 and the second conductive layer 216 extending therebetween, the output 219 of the signal path 215 is electrically connected to the output contact pad 228. In other embodiments, the output 219 could be connected to the output contact pad 228 using only the second contact pad via 232, e.g., the second contact pad via 232 extends between the output 219 defined at the first conductive layer 214 and the output contact pad 228. In still other embodiments, the input 217 and the input contact pad 226, as well as the output 219 and the output contact pad 228, may be electrically connected in other ways, such as using one or more conductive layers, one or more connecting vias, etc.

As shown in FIGS. 5 and 6, a plurality of vias 236 extends from the shield layer 218 toward the opposite surface of the component substrate 202. Referring particularly to FIG. 5, a ground terminal 238 is defined on the upper surface 204 of the component substrate 202, and each via 236 of the plurality of vias 236 extends from the shield layer 218 to the ground terminal 238. The ground terminal 238 is electrically connected to a ground 266 of the device 260, e.g., through one or more ground vias 265. In some embodiments, for instance where the multilayer component 200 is surface mounted on instead of embedded in a device 260, the multilayer component 200 may not include a ground terminal 238 but the vias 236 may extend to an outer surface of the component substrate 202 (e.g., the upper surface 204 or the lower surface 206) and, e.g., directly contact the ground 266 of the device 260 when the multilayer component 200 is mounted on the mounting surface 264 of the device 260.

As shown in FIG. 6, the component substrate 202 defines a perimeter P. The plurality of vias 236 may be defined along the perimeter P of the component substrate 202. The component substrate 202 may have any suitable shape, such as a rectangular parallelopiped shape in which the perimeter P of the component substrate 202 has a generally rectangular shape in an X-Y plane, including four sides 240. As depicted in FIG. 6, a portion of the plurality of vias 236 may be defined along each of the four sides 240 of the perimeter P.

Keeping with FIG. 6, the signal path 215 includes at least one corner 246. For instance, in the depicted embodiment, a conductive material is formed over the first dielectric layer 212 of the plurality of dielectric layers 212 to form the first conductive layer 214 and define the signal path 215. That is, the conductive material of the first conductive layer 214 is in a shape that defines the signal path 215. The signal path 215 includes ten corners 246, where the signal path 215 changes direction in the X-Y plane of the first dielectric layer 212. With the changes in direction at each corner 246, the signal path 215 loops around a central point 248, forming more than one full 360 °(360 degree) loop about the central point 248 without overlapping or intersecting itself in both the X-direction and the Y-direction. For example, while two or more points along the signal path 215 may be located at the same position in the X-direction, each of the two or more points is located at a different position in the Y-direction.

In various embodiments, the signal path 215 may form at least one loop or a partial loop, e.g., the signal path may extend a full 360° about the central point 248 or may extend over only a portion of a 360° path about the central point 248, such as about 340°, about 315°, about 300°, about 180°, about 135°, about 90°, or less. To form the at least one loop or a partial loop, the signal path 215 may include one or more corners 246. Each corner 246 may have an angle greater than about 15°, in some embodiments greater than about 30°, in some embodiments greater than about 45°, and in some embodiments greater than about 60°, such as about 90°.

In some embodiments, the signal path 215 is formed entirely on a single conductive layer. However, in other embodiments, whether formed as a loop, a partial loop, or other shape (such as one or more straight lines), the signal path 215 can respectively include at least two conductive layers spaced apart from each other in the Z-direction of the multilayer component and connected by one or more connecting vias 231. For instance, a first portion of the signal path 215, including the input 217, may be defined on a first conductive layer, and a second portion of the signal path 215, including the output 219, may be defined on a second conductive layer, with at least one connecting via 231 extending between the first portion and the second portion to connect the two portions of the signal path 215. In the embodiment of FIGS. 5 and 6, the first conductive layer 214 defines the signal path 215 including both the input 217 and the output 219, but a connecting via 231 and the second conductive layer 216 help connect the signal path 215 to the output contact pad 228. As described elsewhere herein, in other embodiments, the signal path 215 may include a plurality of portions formed over multiple dielectric layers, e.g., the signal path 215 may include one, two, three, four, or more portions that can be formed from conductive material deposited over separate dielectric layers, and one or more vias may electrically connect two or more portions by extending between portions of the signal path 215 along the Z-direction. Thus, the multilayer component 200 could include one or more inductors, such as one or more loops or coils or partial loops/coils, that are formed over one or more dielectric layers 212 of the multilayer component 200.

As shown in FIGS. 5 and 6, the plurality of vias 236 surround the first conductive layer 214 and the second conductive layer 216 of the multilayer component 200 in the X-direction and the Y-direction. The plurality of vias 236 are defined at regular intervals, but in other embodiments, the plurality of vias 236 are irregularly spaced apart from one another. However the vias 236 are spaced, the plurality of vias 236 disposed about the entire perimeter P of the component substrate 202 may be described as a ring of vias 236, e.g., the plurality of vias 236 ring the multilayer component 200. Further, as illustrated in FIG. 6, the shield layer 218 is formed over the outer dielectric layer 2120 such that the shield layer 218 is formed over the perimeter P of the component substrate 202 and in contact with the plurality of vias 236. As such, the shield layer 218 and the plurality of vias 236 electrically connected thereto surround the first conductive layer 214 and the second conductive layer 216 and, thus, surround the signal path 215.

Each via 236 of the plurality of vias 236 extends from the shield layer 218 to the surface of the component substrate 202 opposite the shield layer 218 along the Z-direction, e.g., the upper surface 204 in the embodiment of FIG. 5. At least one via 236 of the plurality of vias 236 may be a through hole filled with conductive material such that a solid column of conductive material is formed, or at least one via 236 of the plurality of vias 236 may be a through hole having the interior surface thereof plated with conductive material such that the via(s) 236 are hollow. In various embodiments, each of the vias 236 may be filled; each of the vias 236 may be plated, hollow vias; or a mix of filled and plated, hollow vias 236 may be used. Exemplary conductive materials and methods for forming the via through holes are described elsewhere herein. Further, the various other vias described herein, such as the connecting vias 231, first contact pad vias 230, second contact pad vias 232, and ground vias 265, likewise can be filled vias or plated, hollow vias.

The grounded shield layer 218 and plurality of vias 236 form a cage-like grounded shield of the multilayer component 200. For example, as previously described, the plurality of vias 236 can be disposed along the perimeter P of the multilayer component 200 such that the plurality of vias 236 surround the first conductive layer 214 and the second conductive layer 216, or the signal path of the multilayer inductor 200 illustrated in FIGS. 5 and 6. Such grounded shield layer 218 and plurality of vias 236 provide protection from interference for the multilayer component 200, such as from electromagnetic interference radiated from nearby components, and/or may improve performance compared to inductors lacking a shield.

Referring particularly to FIG. 5, in some embodiments, the multilayer component 200 includes a cover 242, which may be, e.g., one or more layers of material that are in addition to the plurality of dielectric layers 212 and the conductive layers 214, 216 that form the component substrate 202. A total thickness tₜₒₜₐₗ of the multilayer component 200 in the Z-direction includes a thickness t of the component substrate 202 and a thickness t_{c} of the cover 242.

The thickness t_{c} of the cover 242 may be about 1000 μm or less, such as within a range of about 100 μm to about 1000 μm, a range of about 200 μm to about 800 μm, a range of about 300 μm to about 700 μm, or a range of about 400 μm to about 600 μm. The total thickness tₜₒₜₐₗ may be about 2000 μm or less, such as about 1500 μm or less, such as about 1250 μm or less, such as about 1000 μm or less, such as about 800 μm or less. The cover 242 may be formed from one or more of a variety of materials as described in greater detail elsewhere herein.

Keeping with FIG. 5, the multilayer component 200 is incorporated into an assembly 250 including the device 260. The device 260 has a device substrate 262 having a mounting surface 264, and the device 260 also includes a ground 266 as discussed above. The ground 266 may be disposed on the mounting surface 264 of the device substrate 262 or may be located within the device substrate 262. Other ports or terminals, such as an input signal terminal 268, may be disposed on the mounting surface 264, as well as one or more components, such as a microprocessor as shown in FIG. 4. The device substrate 262 may be, e.g., a printed circuit board (PCB) or the like formed from any suitable material.

In the embodiment of FIG. 5, the multilayer component 200 is attached to the device 260 such that the multilayer component 200 is embedded in the device substrate 262. However, in other embodiments, the multilayer component 200 may be attached to the device substrate 262, e.g., on the mounting surface 264 of the device substrate 260 such that the multilayer component 200 is a surface mounted component. In some embodiments, the multilayer component 200 may be partially embedded, rather than fully embedded, in the device substrate 262 such that, e.g., at least a portion of the multilayer component 200 extends above or beyond the device substrate 262 along the Z-direction. Further, as depicted in FIG. 5, the multilayer component 200 can be attached to the device 260 such that the plurality of dielectric layers 212, as well as the first conductive layer 214, second conductive layer 216, and shield layer 218 formed over respective dielectric layers 212, are parallel to the mounting surface 264 of the device 260.

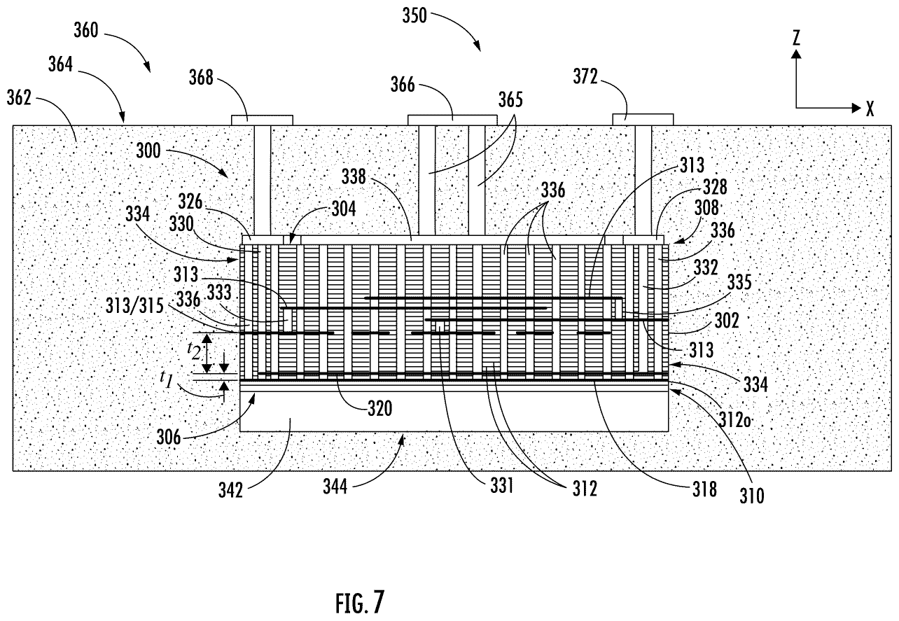

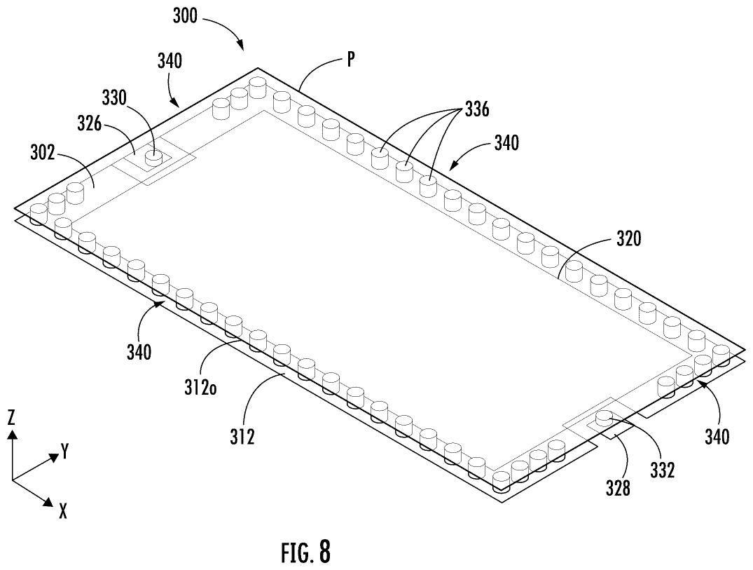

Referring now to FIGS. 7 and 8, another embodiment of a multilayer component is provided, in which the depicted multilayer component 300 includes a resistive layer. It will be appreciated that the multilayer component 300 may include several elements that are similar to the elements of the multilayer components 100, 200 described above. Accordingly, the use of similar reference characters in FIGS. 7 and 8 will be understood to indicate the same or similar features as those illustrated in FIGS. 2 through 6.

FIG. 7 provides a schematic cross-sectional view of an assembly 350 including the multilayer component 300 embedded in a device 360, according to the present disclosure. FIG. 8 provides a top perspective view of the multilayer component 300. It will be appreciated that various elements in FIG. 8 are shown as transparent to depict, e.g., any conductive patterns disposed on layers sandwiched within the stack of layers forming the multilayer component 300. Some elements of the multilayer component 300 shown in FIG. 7 are omitted in FIG. 8 for purposes of illustration.

Referring to FIG. 7, the multilayer component 300 includes a component substrate 302 defining an upper surface 304 and a lower surface 306 opposite the upper surface 304 along a vertical Z-direction. The upper surface 304 extends in a first plane parallel to an X-Y plane defined by a longitudinal X-direction and a lateral Y-direction. The lower surface 306 of the multilayer component 300 extends in a second plane parallel to the X-Y plane. As such, the first plane and the second plane are parallel to one another as well as to the X-Y plane. In the embodiment of FIG. 7, the upper surface 304 is defined at a top 308 and the lower surface 306 is defined at a bottom 310 of the multilayer component 300. It will be appreciated that the X-direction and the Y-direction are perpendicular to one another and are each perpendicular to the Z-direction.

The component substrate 302 includes a plurality of dielectric layers 312, including an outer dielectric layer 3120. A shield layer 318 is formed over the outer dielectric layer 3120. Various conductive layers 313 are formed over other dielectric layers 312, and the conductive layers 313 form a signal path 315 between a first terminal 326 and a second terminal 328. A first contact pad via 330 and a second contact pad via 332 connect conductive layers 313 to the first terminal 326 and the second terminal 328, respectively, with connecting vias 331, 333, 335 extending along the Z-direction between various conductive layers 313 to electrically connect separate conductive layers 313. It will be appreciated that one or more conductive layers 313 may be similar to the first conductive layers 114, 214 described above, and one or more other conductive layers 313 may be similar to the second conductive layers 116, 216 described above. However, in other embodiments, one or more conductive layers 313 may be different from one or more of the conductive layers 114, 116, 214, 216 described elsewhere herein.

As shown in FIGS. 7 and 8, a plurality of vias 336 extends from the shield layer 318 toward the opposite surface of the component substrate 302. Referring particularly to FIG. 7, a ground terminal 338 is defined on the upper surface 304 of the component substrate 302, and each via 336 of the plurality of vias 336 extends from the shield layer 318 to the ground terminal 338. The ground terminal 338 is electrically connected to a ground 366 of the device 360, e.g., through one or more ground vias 365. In some embodiments, for instance where the multilayer component 300 is surface mounted on instead of embedded in a device 360, the multilayer component 300 may not include a ground terminal 338 but the vias 336 may extend to an outer surface of the component substrate 302 (e.g., the upper surface 304 or the lower surface 306) and, e.g., directly contact the ground 366 of the device 360 when the multilayer component 300 is mounted on the mounting surface 364 of the device 360.

As shown in FIG. 8, the component substrate 302 defines a perimeter P, and the plurality of vias 336 are defined along the perimeter P of the component substrate 302. The component substrate 302 may have any suitable shape, such as a rectangular parallelopiped shape in which the perimeter P of the component substrate 302 has a generally rectangular shape in an X-Y plane, including four sides 340. As depicted in FIG. 8, a portion of the plurality of vias 336 may be defined along each of the four sides 340 of the perimeter P.

In the embodiment of FIGS. 7 and 8, the multilayer component 300 includes a resistive layer 320. The resistive layer 320 is formed over a respective one dielectric layer 312 and is disposed in the stack of dielectric and conductive layers between the conductive layers 313 and the shield layer 318. The resistive layer 320 is disposed closer to the shield layer 318 than the other conductive layers 313. For example, in some embodiments, a single dielectric layer 312 is disposed between the shield layer 318 and the resistive layer 320. In other embodiments, a plurality of dielectric layers 312 is disposed between the shield layer 318 and the resistive layer 320, and the plurality of dielectric layers 312 therebetween has a first thickness t₁ in the Z-direction that is less than or equal to a maximum dielectric segment thickness, i.e., the first thickness t₁ is no greater than the maximum dielectric segment thickness. The other conductive layers 313 of the multilayer component 300 are disposed at or near the middle or center of the stack of layers. For example, the shield layer 318 and the resistive layer 320 are disposed at or near an outer surface of the multilayer component 300 (e.g., near the bottom 310 as shown in FIG. 7) while the remaining conductive layers 313 are disposed at or near the middle or center of the multilayer component 300. In the embodiment of FIG. 7, the resistive layer 320 is disposed between the shield layer 318 and the other conductive layers 313, with the first thickness t₁ of dielectric layers 312 separating the resistive layer 320 and the shield layer 318 and a second thickness t₂ of dielectric layers 312 separating the resistive layer 320 and the plurality of conductive layers 313. Other placements or arrangements of the resistive layer 320 and the other conductive layers 313 may be used as well.

It will be appreciated that the resistive layer 320 can have any suitable shape, e.g., to achieve a desired performance value. For instance, in the embodiment of FIG. 7, the resistive material forming the resistive layer 320 is rectangular in shape, but other shapes for the resistive layer 320 may be used as well. Further, as shown in FIGS. 7 and 8, the resistive layer 320 is electrically connected to the first terminal 326 and the second terminal 328 through contact with the first contact via 330 and the second contact via 332. The resistive layer 320 may be electrically connected between the terminals 326, 328 in other ways as well.

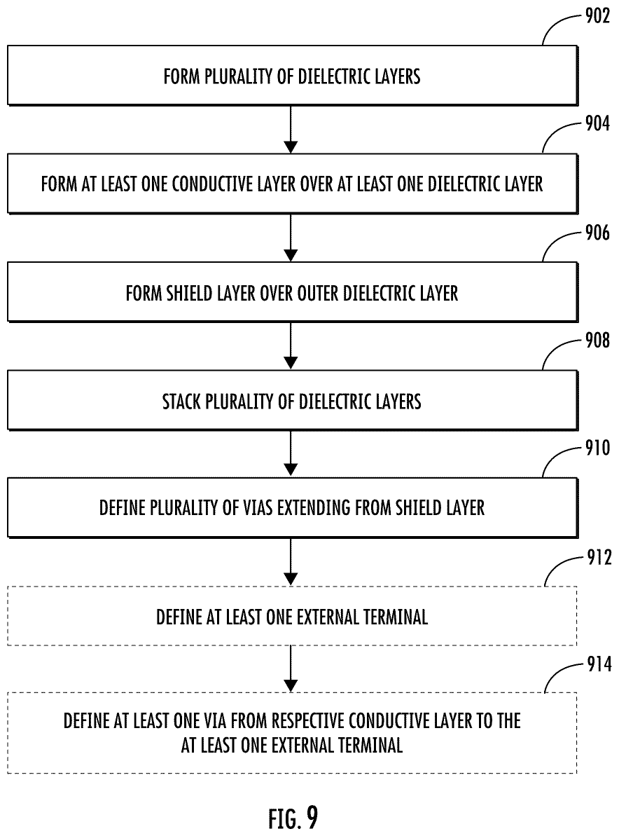

Referring now to FIG. 9, the present subject matter also includes methods for forming multilayer components and methods for forming assemblies as described herein. In general, the method 900 of FIG. 9 will be described herein with reference to the multilayer component 100 of FIGS. 2 through 4, the multilayer component 200 of FIGS. 5 and 6, and the multilayer component 300 of FIGS. 7 and 8. However, it should be appreciated that the disclosed method 900 may be implemented with any suitable multilayer component. In addition, although FIG. 9 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present subject matter.

As shown at (902), a method 900 for forming a multilayer component includes forming a plurality of dielectric layers, such as the dielectric layers 112 of the multilayer component 100 or the dielectric layers 212 of the multilayer component 200. As described in greater detail above, the plurality of dielectric layers can be formed from any suitable dielectric material. The method 900 also includes at (904) forming a at least one conductive layer over at least one dielectric layer. A conductive layer can be formed from a conductive material deposited on or otherwise disposed over a respective one dielectric layer of the plurality of dielectric layers. As one example, as described above with respect to the multilayer component 100, the method 900 can include forming a first conductive layer 114 over a first dielectric layer 112a of the plurality of dielectric layers 112 and a second conductive layer 116 over a second dielectric layer 112b of the plurality of dielectric layers 112. or the conductive layer 212 of the multilayer component 200. As another example, as described above with respect to the multilayer component 200, the method 900 can include forming a first conductive layer 214 over a first dielectric layer 212a of the plurality of dielectric layers 212 and a second conductive layer 216 over a second dielectric layer 212b of the plurality of dielectric layers 212. In further embodiments, as described above with respect to the multilayer component 300, the method 900 can include forming a plurality of conductive layers 313 over a plurality of dielectric layers 312, as well as a resistive layer 320 over a respective dielectric layer 312.

Keeping with FIG. 9, at (906) the method 900 includes forming a shield layer over an outer dielectric layer of the plurality of dielectric layers. The shield layer can include a conductive material deposited on or otherwise disposed over the outer dielectric layer. For instance, the shield layer may be formed as described herein with respect to the shield layer 118 of the multilayer component 100 or the shield layer 218 of the multilayer component 200.

As shown at (908), the method 900 includes stacking the plurality of dielectric layers. As described herein, the plurality of dielectric layers, including any conductive layers formed on one or more dielectric layers of the plurality of dielectric layers, can be stacked in a Z-direction to form a substrate of the multilayer component having a top and a bottom. The outer dielectric layer, having the shield layer formed thereover, can be positioned at either the top or the bottom of the multilayer component along the Z-direction. As described herein, the position of the shield layer and the outer dielectric layer along the Z-direction may depend on the mounting orientation of the multilayer component, e.g., whether the multilayer component is embedded or is surface mounted. In embodiments of the multilayer component including a resistive layer, the resistive layer can be stacked relatively near the shield layer, such as just inward along the Z-direction from the outer dielectric layer over which the shield layer is formed. Further, any other conductive layers can be stacked within the stack of dielectric layers such that the conductive layers are spaced apart along the Z-direction from one another, as well as from the top and the bottom of the substrate. For example, in some embodiments, such as the embodiment of the multilayer component 100 shown in FIG. 2, the shield layer 118 is positioned near the bottom 110 of the multilayer component substrate 102, and each of the first conductive layer 114 and the second conductive layer 116 are spaced apart along the Z-direction from one another as well as both the top 108 and the bottom 110 of the substrate 102. In another example, as shown in FIG. 7, the shield layer 318 is positioned near the bottom 310 of the multilayer component substrate 302, with the resistive layer 320 positioned thereover along the Z-direction (e.g., closer to the top 308 than the shield layer 318) with a first thickness t₁ of dielectric layers 312 disposed therebetween, and each of the remaining conductive layers 313 are disposed around a middle or center of the multilayer component 300, with a second thickness t₂ of dielectric layers 312 disposed between the resistive layer 320 and the nearest conductive layer 313 to the resistive layer 320.

As shown at (910), the method 900 includes defining a plurality of vias that extend from the shield layer. As one example, referring to the embodiment of the multilayer component 200 shown in FIG. 6, a plurality of vias 236 may be defined in the multilayer component 200 such that each via 236 of the plurality of vias 236 extends from the shield layer 218 to the bottom 210 of the component substrate 202.

In some embodiments, the multilayer component can include one or more external terminals that, e.g., are connected to one or more conductive layers of the multilayer component. Accordingly, as shown at (912), the method 900 includes defining at least one external terminal of the multilayer component, and at (914), defining at least one via from a respective conductive layer to the at least one external terminal. As described with respect to the multilayer component 100, in exemplary embodiments, the at least one external terminal can include a first terminal 126, a second terminal 128, and a ground terminal 138. A first terminal via 130 can be defined in the component substrate 102 from the one or more first conductive layers 114 to the first terminal 126 to electrically connect the first conductive layers 114 and the first terminal 126, and a second terminal via 132 can be defined in the component substrate 102 from the one or more second conductive layers 116 to the second terminal 128 to electrically connect the second conductive layers 116 and the second terminal 128. The plurality of vias 136 can extend from the shield layer 118 to the ground terminal 138. As shown in FIG. 2, each of the first terminal 126, second terminal 128, and ground terminal 138 may be defined on the same external surface of the substrate 102, such as at the top 108 of the substrate 102, but in other embodiments, one or more of the external terminals 126, 128, 138 of the multilayer component 100 may be defined on other external surfaces.

As another example, defining at least one external terminal and at least one via extending between a conductive layer and the at least one external terminal can include defining an input contact pad 226 and an output contact pad 228, as well as defining a first contact pad via 230 and a second contact pad via 232. The first contact pad via 230 extends from an input 217 of a signal path 215 defined by the first conductive layer 214 of the multilayer component 200 to the input contact pad 226. The second contact pad via 232 extends from the second conductive layer 216 to the output contact pad 228, with a connecting via 231 defined in the substrate 202 from the output 219 of the signal path 215 to the second conductive layer 216.

Although not shown in FIG. 9, it will be understood that, in some embodiments, the method 900 also includes forming a cover over the outer conductive layer. For instance, as shown in FIGS. 2, 5, and 7, respectively, the multilayer component 100 can include a cover 142 disposed over the outer dielectric layer 1120, the multilayer component 200 can include a cover 242 disposed over the outer dielectric layer 2120, and the multilayer component 300 can include a cover 342 disposed over the outer dielectric layer 3120. Additionally, or alternatively, one or more dielectric layers may be disposed over the outer conductive layer, e.g., such that the shield layer does not define an outer surface of the component substrate (the cover or a dielectric layer forms the outer surface), although in some embodiments, the shield layer may define an outer surface of the substrate of the multilayer component.

In methods of forming an assembly including a multilayer component as described herein, the method may include attaching the multilayer component to a device substrate of a device of the assembly. For example, as shown in FIGS. 2 and 4, attaching the multilayer component 100 to the device 160 includes embedding the multilayer component 100 in the device substrate 162. As another example, as illustrated in FIG. 5, attaching the multilayer component 200 to the device 260 includes embedding the multilayer component 200 in the device substrate 262. As a third example, as illustrated in FIG. 7, attaching the multilayer component 300 to the device 360 includes embedding the multilayer component 300 in the device substrate 362. In other embodiments, attaching the multilayer component to the device can include attaching the multilayer component to a mounting surface defined by a device substrate of the device, such as the mounting surface 164 of the device 160, the mounting surface 264 of the device 262, or the mounting surface 364 of the device 362. Methods of forming an assembly can also include forming electrical connections between the device and the multilayer component. For instance, a ground via 165 may be formed between the ground terminal 138 of the multilayer component 100 and the ground 166 of the device 160.

### Applications

The various embodiments of multilayer components described herein may find application in any suitable type of electrical component. The multilayer components may find particular application in devices that receive, transmit, or otherwise employ high frequency radio signals. Further, the multilayer components may find particular application in devices where volume, and not just mass, is important to minimize board space. Example applications include wearable technology and satellites, such as CubeSats, as well as other applications.

These and other modifications and variations of the present invention may be practiced by those of ordinary skill in the art, without departing from the spirit and scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

What is claimed is:

1. A multilayer component, comprising:
a plurality of dielectric layers including an outer dielectric layer, the plurality of dielectric layers stacked in a Z-direction to form a substrate having a top and a bottom;
a conductive layer formed over a respective one dielectric layer of the plurality of dielectric layers, the conductive layer disposed within the stacked plurality of dielectric layers such that the conductive layer is spaced apart from both the top and the bottom of the substrate along the Z-direction;
a shield layer formed over the outer dielectric layer; and
a plurality of vias extending from the shield layer.

2. The multilayer component of claim 1, wherein the substrate defines a perimeter, and wherein each via of the plurality of vias is defined along the perimeter of the substrate such that the plurality of vias surround the conductive layer in an X-direction and a Y-direction, the X-direction and the Y-direction perpendicular to one another and each perpendicular to the Z-direction.

3. The multilayer component of claim 2, wherein the perimeter has a generally rectangular shape including four sides, and wherein a portion of the plurality of vias is defined along each of the four sides of the perimeter.

4. The multilayer component of claim 1, wherein at least one via of the plurality of vias is plated with a conductive material.

5. The multilayer component of claim 1, wherein at least one via of the plurality of vias is filled with a conductive material.

6. The multilayer component of claim 1, wherein the substrate defines a perimeter, and wherein the shield layer is formed over the outer dielectric layer such that the shield layer extends to the perimeter of the substrate.

7. The multilayer component of claim 1, wherein the conductive layer is a first conductive layer formed over a first dielectric layer of the plurality of dielectric layers, and further comprising a second conductive layer formed over a second dielectric layer of the plurality of dielectric layers, the second conductive layer overlapping the first conductive layer in an X-direction and a Y-direction to form an overlap area, the X-direction and the Y-direction perpendicular to one another and each perpendicular to the Z-direction.

8. The multilayer component of claim 7, wherein the first conductive layer is electrically connected to a first terminal and the second conductive layer is electrically connected to a second terminal.

9. The multilayer component of claim 8, wherein a first terminal via extends from the first conductive layer to the first terminal, wherein a second terminal via extends from the second conductive layer to the second terminal, and wherein the first terminal and the second terminal are disposed on an outer surface of the substrate.

10. The multilayer component of claim 1, wherein the conductive layer defines a signal path, and wherein the signal path comprises an input and an output.

11. The multilayer component of claim 10, wherein the signal path comprises at least one corner.

12. The multilayer component of claim 10, wherein the input is electrically connected to an input contact pad and the output is electrically connected to an output contact pad, and wherein at least one first contact pad via electrically connects the input of the signal path with the input contact pad and at least one second contact pad via electrically connects the output of the signal path with the output contact pad.

13. The multilayer component of claim 1, wherein the multilayer component is configured for embedding in a device.

14. The multilayer component of claim 1, further comprising a resistive layer formed over a respective one dielectric layer of the plurality of dielectric layers, the resistive layer disposed between the shield layer and the conductive layer.

15. An assembly, comprising:
a device having a device substrate and a ground defined on the device substrate; and
a multilayer component attached to the device substrate, the multilayer component comprising:
a plurality of dielectric layers including an outer dielectric layer, the plurality of dielectric layers stacked in a Z-direction to form a multilayer component substrate having a top and a bottom;
a conductive layer formed over a respective one dielectric layer of the plurality of dielectric layers, the conductive layer disposed within the stacked plurality of dielectric layers such that the conductive layer is spaced apart from both the top and the bottom of the multilayer component substrate along the Z-direction;
a shield layer formed over the outer dielectric layer; and
a plurality of vias extending from the shield layer,
wherein each via of the plurality of vias is electrically connected to the ground.

16. The assembly of claim 15, wherein the device substrate defines a mounting surface, wherein the multilayer component is embedded within the device such that the multilayer component is spaced apart from the mounting surface of the device substrate in the Z-direction.

17. The assembly of claim 15, wherein each via of the plurality of vias extends from the shield layer to a ground terminal, the ground terminal electrically connected to the ground.

18. The assembly of claim 15, wherein the multilayer component substrate defines a perimeter, and wherein each via of the plurality of vias is defined along the perimeter of the multilayer component substrate such that the plurality of vias surround the conductive layer in an X-direction and a Y-direction, the X-direction and the Y-direction perpendicular to one another and each perpendicular to the Z-direction.

19. A method for forming a multilayer component, the method comprising:
forming a plurality of dielectric layers, the plurality of dielectric layers including an outer dielectric layer;
forming a conductive layer, the conductive layer formed from a conductive material disposed over a respective one dielectric layer of the plurality of dielectric layers;
forming a shield layer, the shield layer formed from the conductive material disposed over the outer dielectric layer;
stacking the plurality of dielectric layers in a Z-direction to form a substrate; and
defining a plurality of vias along the perimeter of the substrate,
wherein the plurality of vias extend from the shield layer to an outer surface of the substrate opposite the shield layer along the Z-direction.
